(19) United States
(12) Patent Application Publication
(10) Pub. No.: US 2026/0228883 A1
(43) Pub. Date: Aug. 6, 2026

(54) SUBSTRATE PROCESSING APPARATUS, SUBSTRATE PROCESSING METHOD, AND RECORDING MEDIUM

(71) Applicant: TOKYO ELECTRON LIMITED, Tokyo (JP)

(72) Inventor: Akinori TANAKA, Kumamoto (JP)

(21) Appl. No.: 19/457,103

(22) Filed: Jan. 22, 2026

(30) Foreign Application Priority Data
Feb. 5, 2025 (JP) 2025-017441
Sep. 24, 2025 (JP) 2025-158053

(51) Int. Cl. G06T 7/00; B08B 3/08; B08B 13/00; G01M 99/00; G06T 7/13; G06T 7/174; G06T 7/55; G06T 7/60; H10P 72/00

(52) U.S. Cl. CPC G06T 7/001; B08B 3/08; B08B 13/00; G01M 99/008; G06T 7/13; G06T 7/174; G06T 7/55; G06T 7/60; G06T 2207/30148; H10P 72/0414

(57) ABSTRACT

A substrate processing apparatus, includes: a rotary holder configured to hold and rotate a substrate; an arm configured to hold nozzles; a driver configured to drive the arm so that the nozzles move between a standby position and a processing position; a capturer configured to capture an image of the nozzles; a supplier configured to supply processing liquids to the nozzles; and a controller. The controller is configured to perform: a first process of causing the capturer to capture images of the nozzles located at the processing position; a second process of detecting tip end portions of the nozzles; a third process of detecting whether a droplet is hanging from an injection port of the tip end portions; a fourth process of calculating a height of the droplet; and a fifth process of determining whether an abnormality exists based on the height.

### CROSS-REFERENCE TO RELATED APPLICATIONS

This application is based upon and claims the benefit of priority from Japanese Patent Application No. 2025-017441, filed on Feb. 5, 2025, and Japanese Patent Application No. 2025-158053, filed on Sep. 24, 2025, the entire contents of which are incorporated herein by reference.

### TECHNICAL FIELD

The present disclosure relates to a substrate processing apparatus, a substrate processing method, and a recording medium.

### BACKGROUND

Patent Document 1 discloses a substrate processing method in which a monitoring target is specified from a plurality of monitoring target candidates inside a chamber, and image conditions are changed based on the monitoring target, thereby performing a monitoring process for each monitoring target based on more appropriate image data.

### PRIOR ART DOCUMENT

### Patent Document

Patent Document 1: Japanese Laid-Open Publication No. 2021-190511

### SUMMARY

According to one embodiment of the present disclosure, a substrate processing apparatus includes: a rotary holder configured to hold and rotate a substrate; an arm configured to hold a plurality of nozzles; a driver configured to drive the arm so that the plurality of nozzles move between a standby position outside the substrate held by the rotary holder and a processing position above the substrate held by the rotary holder; a capturer configured to capture the plurality of nozzles; a supplier configured to supply processing liquids to each of the plurality of nozzles; and a controller, wherein the controller is configured to control the supplier and the capturer to perform a first process of causing the capturer to capture images of the plurality of nozzles located at the processing position when the supply of the processing liquids to the plurality of nozzles is stopped, a second process of detecting tip end portions of the plurality of nozzles based on the images captured in the first process, a third process of detecting whether a droplet is hanging from an injection port of each of the tip end portions detected in the second process based on the images captured in the first process, a fourth process of calculating a height of the droplet when the hanging droplet is detected in the third process, and a fifth process of determining whether an abnormality exists based on the height of the droplet calculated in the fourth process.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing an example of a substrate processing system.

FIG. 2 is a diagram schematically showing an example of a liquid processing unit.

FIG. 3 is a block diagram showing an example of main components of the substrate processing system.

FIG. 4 is a schematic diagram showing an example of a hardware configuration of a controller.

FIG. 5 is a flowchart for explaining an example of a substrate process.

FIG. 6 is a flowchart for explaining an example of a process of detecting liquid leakage from a nozzle.

FIG. 7A is a diagram showing an example of an image captured by a capturer, and FIG. 7B is a diagram showing an example of a previously captured image in which a mask region has been set.

FIG. 8A is a diagram showing an example of an extracted image obtained by performing an edge extraction process on a difference image, FIG. 8B is a diagram showing an example of a captured image in which a region surrounding entire of a plurality of nozzles has been set, and FIG. 8C is a diagram showing an example of a captured image in which a region surrounding each nozzle has been set.

FIG. 9A is a diagram showing an example of a difference image in a vicinity of an injection port of a nozzle, FIG. 9B is a diagram showing an example of an extracted image obtained by performing an edge extraction process on the difference image of FIG. 9A without using an elimination filter, FIG. 9C is a diagram showing an example of a state in which a droplet is erroneously detected in the extracted image of FIG. 9B, and FIG. 9D is a diagram showing an example of an extracted image obtained by performing an edge extraction process on the difference image of FIG. 9A using an elimination filter.

FIG. 10A is a diagram showing an example of a captured image of a vicinity of an injection port of a nozzle and a droplet hanging from the injection port, FIG. 10B is a diagram showing an example of an image in which a lower region of the captured image has been cut out, FIG. 10C is a diagram showing an example of an extracted image in which the lower region has been subjected to an edge extraction process, FIG. 10D is a diagram showing an example of a discrimination image in which a shape of an object in contact with the injection port of the nozzle has been determined, and FIG. 10E is a diagram for explaining a method of calculating a height of the droplet in the captured image of the vicinity of the injection port of the nozzle and the droplet hanging from the injection port.

FIG. 11A is a diagram showing an example of an object in contact with an injection port of a nozzle when an aspect ratio is relatively small, and FIG. 11B is a diagram showing an example of an object in contact with an injection port of a nozzle when an aspect ratio is relatively large.

FIG. 12 is a graph showing an example of a change in a height of the droplet calculated for each frame when a nozzle is moving at a processing position.

FIG. 13 is a diagram schematically showing another example of the liquid processing unit.

FIG. 14A is a diagram showing another example of the captured image captured by the capturer, FIG. 14B is a diagram showing an example of a cropped image obtained by cropping the upper portion of FIG. 14A, FIG. 14C is a diagram showing an example of a binarized image obtained by binarizing the cropped image of FIG. 14B, and FIG. 14D is a diagram showing a state in which a region surrounding each nozzle is set in the captured image of FIG. 14A.

FIG. 15A is a diagram showing an example of an image captured by a capturer when a light reflection region is present on an upper surface of a substrate, and FIG. 15B is a diagram showing another example of the image captured by the capturer when a light reflection region is present on the upper surface of the substrate.

FIG. 16A is a diagram showing an example of a captured image of a vicinity of the injection port of the nozzle and a droplet hanging from the injection port of the nozzle when the light reflection region is spaced apart from the injection port of the nozzle, and FIG. 16B is a diagram showing an example of a captured image of the vicinity of the injection port of the nozzle and the droplet hanging from the injection port when the light reflection region is in the vicinity of the injection port of the nozzle.

FIG. 17 is a graph showing another example of the change in a height of the droplet calculated for each frame.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the following description, the same components or components having the same functions will be denoted by same reference numerals, and redundant descriptions thereof will be omitted. In addition, in this specification, when referring to top, bottom, right, and left in a figure, a direction of the reference numerals in the figure will be used as a reference.

### [Substrate Processing System]

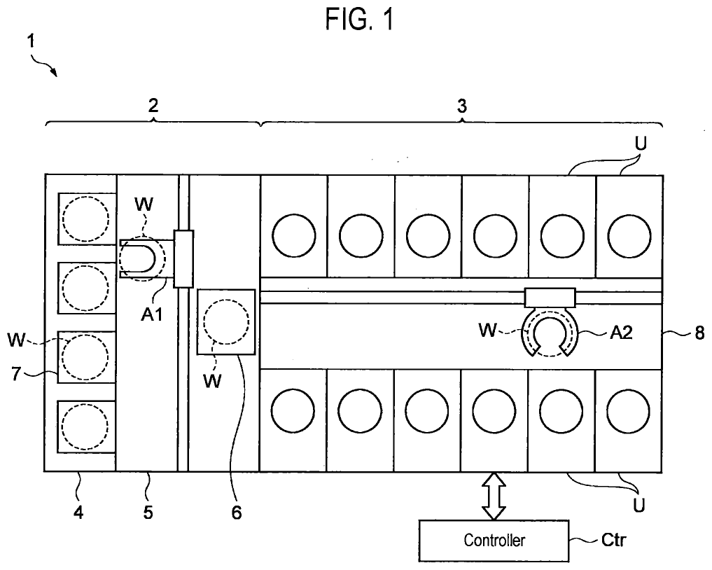

First, a substrate processing system 1 (substrate processing apparatus) configured to process substrates W will be described with reference to FIG. 1. The substrate processing system 1 includes a loading/unloading station 2, a processing station 3, and a controller Ctr (controller). The loading/unloading station 2 and the processing station 3 may be arranged in a row along a horizontal direction.

The substrate W may have a circular plate shape or may have a plate shape other than a circular shape, such as a polygonal shape or the like. The substrate W may have a cutout at which a portion of the substrate W is cut out. The cutout is, for example, a notch (a groove such as a U-shaped groove, a V-shaped groove, or the like) or a linear portion (so-called “orientation flat”) extending in a straight line. The substrate W is, for example, a semiconductor substrate (silicon wafer), a glass substrate, a mask substrate, a flat panel display (FPD) substrate, or various other types of substrates. A diameter of the substrate W is, for example, approximately 200 mm to 450 mm.

The loading/unloading station 2 includes a placement portion 4, a loading/unloading portion 5, and a shelf unit 6. The placement portion 4 includes a plurality of stages (not shown) arranged in a width direction (up-down direction in FIG. 1). Each stage is configured to be able to place a carrier 7 on the stage. The carrier 7 is configured to accommodate at least one substrate W in a sealed state. The carrier 7 includes an opening/closing door (not shown) for loading and unloading the substrate W.

The loading/unloading portion 5 is disposed adjacent to the placement portion 4 in a direction in which the loading/unloading station 2 and the processing station 3 are aligned (left-right direction in FIG. 1). The loading/unloading portion 5 includes an opening/closing door (not shown) provided with respect to the placement portion 4. When both the opening/closing door of the carrier 7 and the opening/closing door of the loading/unloading portion 5 are opened in a state in which the carrier 7 is placed on the placement portion 4, an interior of the loading/unloading portion 5 and the interior of the carrier 7 are brought into communication with each other.

The loading/unloading portion 5 includes a transfer arm A1 and a shelf unit 6. The transfer arm A1 is configured to be movable horizontally, movable vertically in a vertical direction, and rotatable about a vertical axis. The transfer arm A1 is configured to take out the substrate W from the carrier 7 and deliver the substrate W to the shelf unit 6, and also to receive the substrate W from the shelf unit 6 and return the substrate W to the carrier 7. The shelf unit 6 is located in a vicinity of the processing station 3 and is configured to accommodate the substrate W.

The processing station 3 includes a transfer portion 8 and a plurality of liquid processing units U. The transfer portion 8 extends horizontally, for example, in a direction in which the loading/unloading station 2 and the processing station 3 are aligned (left-right direction in FIG. 1). The transfer portion 8 includes a transfer arm A2. The transfer arm A2 is configured to be movable horizontally, movable vertically in the vertical direction, and rotatable about a vertical axis. The transfer arm A2 is configured to take out the substrate W from the shelf unit 6 and deliver the substrate W to the liquid processing unit U, and also to receive the substrate W from the liquid processing unit U and return the substrate W into the shelf unit 6.

The plurality of liquid processing units U are arranged in a row along the longitudinal direction of the transfer portion 8 (left-right direction in FIG. 1) on both sides of the transfer portion 8. A configuration of the liquid processing unit U will be described later.

The controller Ctr, as will be described in detail later, is configured to control the substrate processing system 1 either partially or entirely.

### [Liquid Processing Unit]

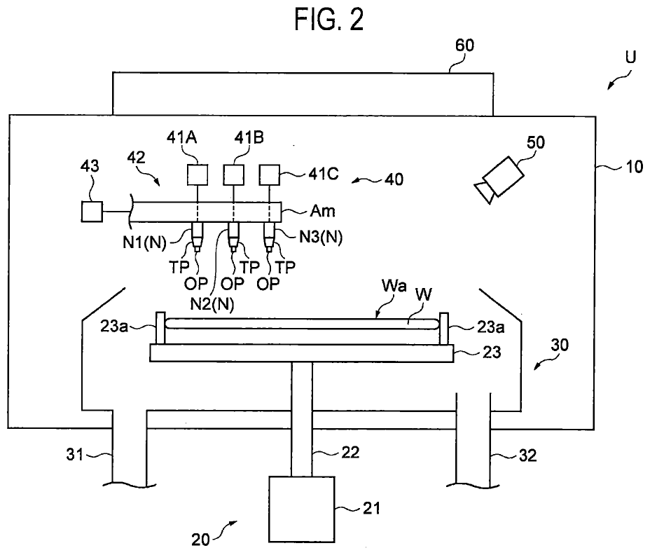

Next, the liquid processing unit U will be described with reference to FIG. 2. The liquid processing unit U includes a housing 10, a driver 20 (rotary holder), a cup 30, a supplier 40, a capturer 50, and a blower 60.

The housing 10 is configured so that the substrate W can be loaded into and unloaded from the housing 10. A loading/unloading port (not shown) is formed in a side wall of the housing 10. The substrate W is transferred into the housing 10 and also unloaded from the housing 10 to the outside through the loading/unloading port by the transfer arm A2.

The driver 20 includes a drive source 21, a shaft 22, and a holder 23. The drive source 21 is configured to operate based on an operation signal from the controller Ctr, and to rotate the shaft 22 and raise and lower the shaft 22. The drive source 21 is, for example, a power source such as an electric motor or an electric actuator.

The holder 23 has, for example, a circular plate shape and is provided at a tip end portion of the shaft 22. Therefore, the holder 23 rotates via the shaft 22, and is raised and lowered via the shaft 22, by the operation of the drive source 21.

A plurality of holding members 23a protruding upward are provided on an upper surface of the holder 23. The plurality of holding members 23a are configured to hold an outer peripheral edge of the substrate W by moving in a radial direction of the holder 23. That is, the substrate W is held in a substantially horizontal state above the upper surface of the holder 23 by the plurality of holding members 23a.

The driver 20 is configured to rotate the substrate W around a central axis (rotation axis) perpendicular to an upper surface Wa of the substrate W while holding the substrate W in a state in which a posture of the substrate W is substantially horizontal. The driver 20 is configured so that the drive source 21 raises and lowers the shaft 22, thereby moving the holder 23 up and down between a lowered position (see FIG. 2) and a raised position (not shown). As illustrated in FIG. 2, at the lowered position, the substrate W held by the plurality of holding members 23a is located inside the cup 30. On the other hand, at the raised position, the substrate W held by the plurality of holding members 23a is located above the cup 30.

The cup 30 is provided to surround the holder 23 from the outside. The cup 30 is configured to collect processing liquids (e.g., chemical liquids L1 and L2 and a cleaning liquid L3, which will be described later) that scatter from the outer peripheral edge of the substrate W toward the surroundings when the substrate W is held and rotated by the driver 20. A drain port 31 and an exhaust port 32 are provided at a bottom portion of the cup 30.

The drain port 31 is configured to drain the processing liquid collected by the cup 30 to the outside of the liquid processing unit U. The exhaust port 32 is configured to discharge downward flow formed around the substrate W by the blower 60 to the outside of the liquid processing unit U. The downward flow is accompanied by gas generated around the substrate W as the substrate W is processed with the processing liquid.

The supplier 40 is configured to supply the processing liquids (the chemical liquids L1 and L2, and the cleaning liquid L3) to the upper surface Wa of the substrate W. The supplier 40 includes supply mechanisms 41A, 41B and 41C, a nozzle unit 42, and a drive source 43 (driver).

The supply mechanism 41A is configured to operate based on an operation signal from the controller Ctr and to send out the chemical liquid L1 stored in a container (not shown) by a liquid sending mechanism (not shown) such as a pump or the like. The chemical liquid L1 may include, for example, an alkaline chemical liquid for processing the substrate W (e.g., for removing dirt or foreign matter, etching, or the like). The alkaline chemical liquid may include, for example, an SC-1 liquid (a mixture of ammonia, hydrogen peroxide and pure water), and the like.

The supply mechanism 41B is configured to operate based on an operation signal from the controller Ctr and to send out the chemical liquid L2 stored in a container (not shown) by a liquid sending mechanism (not shown) such as a pump or the like. The chemical liquid L2 may include, for example, an acidic chemical liquid for processing the substrate W (e.g., for removing dirt or foreign matter, etching, or the like). The acidic chemical liquid may include, for example, an SC-2 liquid (a mixture of hydrochloric acid, hydrogen peroxide solution and pure water), an SPM (a mixture of sulfuric acid and hydrogen peroxide solution), an HF/HNO₃ liquid (a mixture of hydrofluoric acid and nitric acid), and the like.

The supply mechanism 41C is configured to operate based on an operation signal from the controller Ctr and to send out the cleaning liquid L3 stored in a container (not shown) using a liquid sending mechanism (not shown) such as a pump or the like. The cleaning liquid L3 may include, for example, deionized water (DIW), ozone water, carbonated water (CO₂ water), ammonia water, and the like.

The nozzle unit 42 is configured to inject the chemical liquids L1 and L2 and the cleaning liquid L3 supplied from the supply mechanisms 41A, 41B and 41C onto the upper surface Wa of the substrate W, respectively. The nozzle unit 42 includes nozzles N1, N2 and N3 and an arm Am. The nozzle N1 is connected to the container that stores the chemical liquid L1 via a pipe (not shown). The nozzle N2 is connected to the container that stores the chemical liquid L2 via a pipe (not shown). The nozzle N3 is connected to the container that stores the cleaning liquid L3 via a pipe (not shown). The arm Am holds the nozzles N1, N2 and N3. Further, in the present specification, the nozzles N1, N2 and N3 may be collectively referred to as “nozzle N.”

The drive source 43 is configured to move the arm Am in a height direction and a horizontal direction based on a signal from the controller Ctr. The drive source 43 is configured to move the arm Am between a standby position and a processing position. At the standby position, the nozzles N1, N2 and N3 and the arm Am are located outside the substrate W held by the plurality of holding members 23a when viewed from above. At the processing position, the nozzles N1, N2 and N3 and the arm Am are located above the substrate W held by the plurality of holding members 23a. At the processing position, the nozzles N1, N2 and N3 and the arm Am may move horizontally above the substrate W held by the plurality of holding members 23a.

As illustrated in FIG. 2, each tip end portion TP of the nozzles N1, N2 and N3 extends along up-down direction. Therefore, injection ports OP provided at lower ends of the tip end portions TP are opened downward.

The capturer 50 is configured to operate based on an operation signal from the controller Ctr and to capture moving images of the arm Am, the nozzles N1, N2 and N3 held by the arm Am, and the surroundings. The capturer 50 is disposed inside the housing 10. The capturer 50 may be directly attached to a wall surface of the housing 10, or may be indirectly attached to the housing 10 via a support member or the like. The capturer 50 is configured to transmit data of captured images to the controller Ctr.

The blower 60 is disposed in a ceiling portion of the housing 10 above the driver 20 and the cup 30. When viewed from above, the blower 60 covers the entire substrate W held by the plurality of holding members 23a. The blower 60 operates based on an operation signal from the controller Ctr, and is configured to form the downward flow toward the upper surface Wa of the substrate W held by the plurality of holding members 23a.

### [Controller]

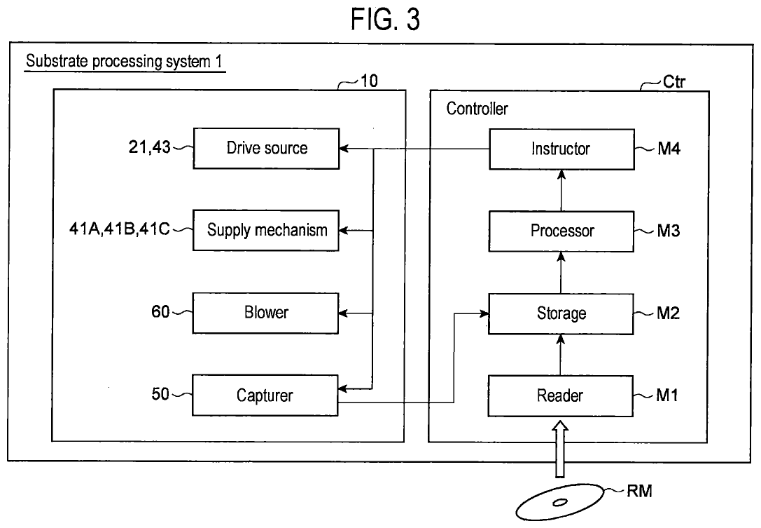

As shown in FIG. 3, the controller Ctr includes a reader M1, a storage M2, a processor M3, and an instructor M4, as functional modules. These functional modules are nothing more than a division of functions of the controller Ctr into a plurality of modules for convenience, and do not necessarily mean that a hardware that makes up the controller Ctr is divided into such modules. Each functional module is not limited to being implemented by executing a program, and may also be implemented by a dedicated electrical circuit (e.g., a logic circuit) or an integrated circuit (ASIC: Application Specific Integrated Circuit) that integrates the electrical circuit.

The reader M1 is configured to read programs from a non-transitory computer-readable recording medium RM (device). The recording medium RM records programs (program products) for operating the individual components of the substrate processing system 1 (the drive sources 21 and 43, the supply mechanisms 41A, 41B and 41C, the capturer 50, the blower 60, and the like). The recording medium RM is, for example, a semiconductor memory, an optical recording disk, a magnetic recording disk, or a magneto-optical recording disk. The recording medium RM may be built into the substrate processing system 1 or may be provided separately from the substrate processing system 1.

The storage M2 is configured to store various types of data. For example, the storage M2 may store programs read from the recording medium RM by the reader M1, setting data input by an operator via an external input device (not shown), and the like. The storage M2 may store, for example, data of images captured by the capturer 50. The storage M2 may store data of a feature map (described later) or data of a template image (described later).

The processor M3 is configured to process various types of data, and may be configured to generate operation signals for operating the individual components of the substrate processing system 1, based on, for example, the various types of data stored in the storage M2.

The instructor M4 is configured to transmit the operation signals generated by the processor M3 to the individual components of the substrate processing system 1.

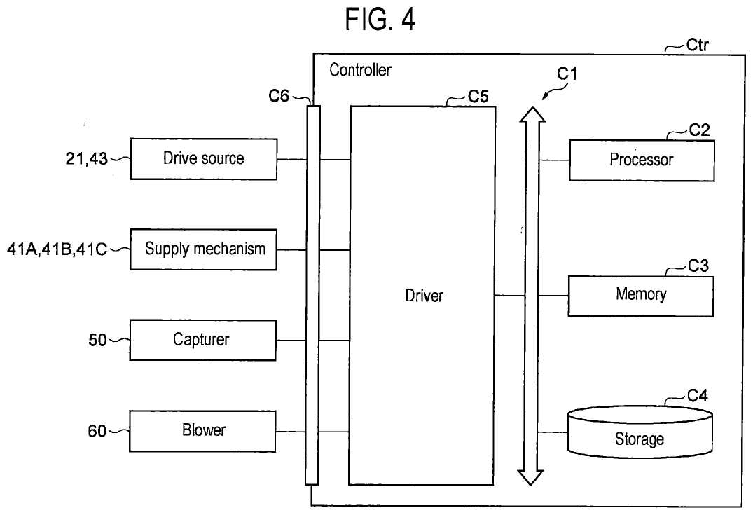

The hardware of the controller Ctr may be configured, for example, by a single or a plurality of computers for control. The controller Ctr may include, for example, a circuit C1 shown in FIG. 4 as a hardware configuration. The circuit C1 may be configured with electrical circuit elements (circuitry). The circuit C1 may include, for example, a processor C2, a memory C3, a storage C4, a driver C5, and an input/output port C6. The processor C2 executes programs in cooperation with at least one of the memory C3 or the storage C4 and executes input and output of signals via the input/output port C6, thereby forming each of the above-mentioned functional modules. The memory C3 and the storage C4 function as the storage M2. The driver C5 is a circuit that drives each of the individual components of the substrate processing system 1. The input/output port C6 performs the input and output of signals between the driver C5 and the individual components of the substrate processing system 1.

The substrate processing system 1 may include a single controller Ctr, or may include a controller group (controller) composed of a plurality of controllers Ctr. In the latter case, each of the above-mentioned functional modules may be implemented by a single controller Ctr or may be implemented by a combination of two or more controllers Ctr. When the controller Ctr is composed of a plurality of computers (circuits C1), each of the above-mentioned functional modules may be implemented by a single computer (circuit C1), or may be implemented by a combination of two or more computers (circuits C1). The controller Ctr may include a plurality of processors C2. In this case, each of the above-mentioned functional modules may be implemented by a single processor C2 or may be implemented by a combination of two or more processors C2.

### [Substrate Processing Method]

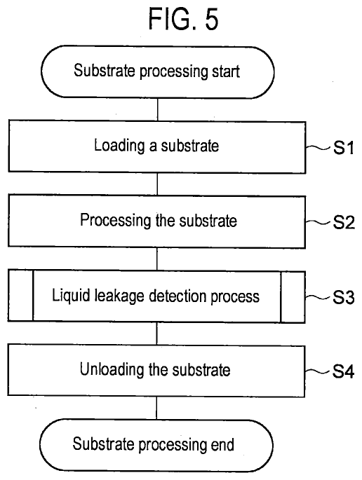

Next, a method for processing the substrate W will be described with reference to FIGS. 5 to 11A and 11B.

First, the controller Ctr instructs the transfer arms A1 and A2 to take out one substrate W from the carrier 7 and transfer the substrate W toward one of the liquid processing units U. Next, in the one of the liquid processing units U, the controller Ctr instructs the drive source 21 to raise the holder 23 to the raised position. Subsequently, the controller Ctr instructs the transfer arm A2 to load the substrate W into the housing 10 and hold the substrate W on the plurality of holding members 23a. Thus, the substrate W is loaded into the liquid processing unit U (housing 10) (see step S1 in FIG. 5).

Next, the controller Ctr instructs the drive source 21 to lower the holder 23 to the lowered position (see FIG. 2). Thereafter, the controller Ctr instructs the drive source 21 to rotate the holder 23 at a predetermined number of rotations. Subsequently, the controller Ctr instructs the drive source 43 to operate the arm Am so that the nozzles N1, N2 and N3 are positioned above approximately a center of the substrate W.

Next, the controller Ctr instructs the supply mechanisms 41A, 41B and 41C to process the substrate W with the processing liquids (see step S2 in FIG. 5). For example, the supply mechanism 41A may supply the chemical liquid L1 to the upper surface Wa of the rotating substrate W, the supply mechanism 41B may supply the chemical liquid L2 to the upper surface Wa of the rotating substrate W, and then the supply mechanism 41C may supply the cleaning liquid L3 to the upper surface Wa of the rotating substrate W. Thereafter, the controller Ctr instructs the supply mechanisms 41A, 41B and 41C to stop supplying the processing liquids.

Next, a process of detecting liquid leakage from the nozzles N1, N2 and N3 is performed (see step S3 in FIG. 5). The process of detecting liquid leakage will be described in detail later.

Next, the controller Ctr instructs the drive source 21 to raise the holder 23 to the raised position. Thereafter, the controller Ctr instructs the transfer arm A2 to transfer the substrate W out of the housing 10. Thus, the substrate W is unloaded from the liquid processing unit U (housing 10), and the substrate processing is terminated (see step S4 in FIG. 5).

### [Liquid Leakage Detection Process]

Next, details of the liquid leakage detection process will be described.

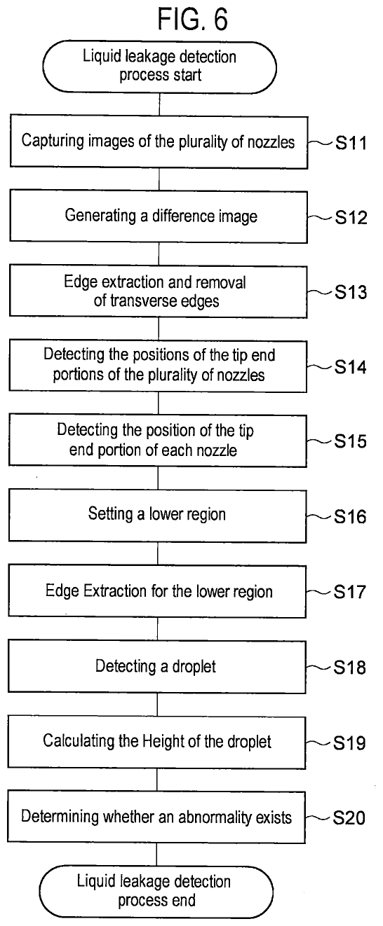

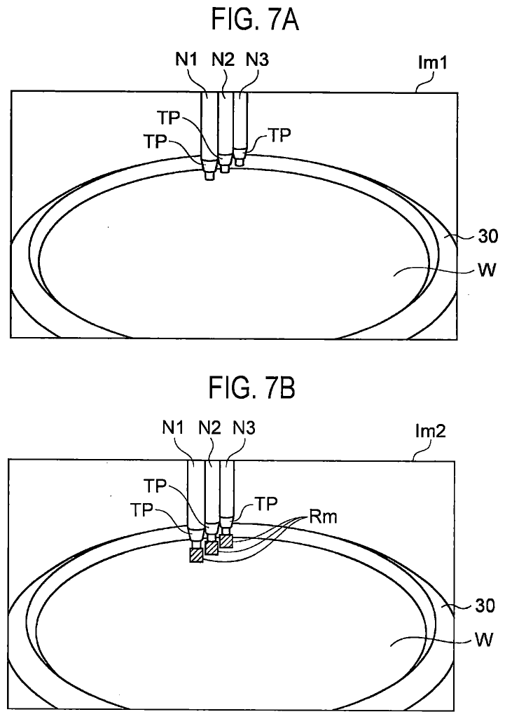

First, the controller Ctr instructs the drive source 43 to operate the arm Am to move the nozzles N1, N2 and N3 and the arm Am from the processing position to the standby position. Thereafter, while the supply of the processing liquids is stopped and the arm Am is moving from the processing position to the standby position, the controller Ctr instructs the capturer 50 to capture moving images of the nozzles N1, N2 and N3 at the processing position (see step S11 in FIG. 6). The capturer 50 transmits each captured image to the controller Ctr. FIG. 7A shows an example of the image captured by the capturer 50. In addition, a frame rate of the capturer 50 may be set to an arbitrary value, for example, approximately 1 frame/second to 1000 frames/second.

Next, the controller Ctr generates a difference image based on a currently captured image Im1 (see FIG. 7A) and a previously captured image Im2 (see FIG. 7B) (see step S12 in FIG. 6). The currently captured image Im1 is the currently captured image among the images captured by the capturer 50. The previously captured image Im2 is the image captured immediately preceding (one frame before) the currently captured image. The difference image may be generated, for example, by subtracting each pixel value of the previously captured image Im2 from each pixel value of the currently captured image Im1.

When generating the difference image, a mask region may be set in the previously captured image Im2. Specifically, a mask region Rm (see FIG. 7B) may be respectively set below each of the injection port OP in the previously captured image Im2 so as to be in contact with the injection port OP of each of the nozzles N1, N2 and N3. In this case, when a difference between the currently captured image Im1 and the previously captured image Im2 is calculated, pixel values of a region of the currently captured image Im1 corresponding to the mask region Rm remain unchanged in the difference image. Further, this mask region may be the same region as a lower region R4 described below.

Before generating the difference image, brightness of the currently captured image Im1 may be adjusted. In this case, it is possible to facilitate the detection of liquid leakage. Before generating the difference image, a size of the currently captured image Im1 may be reduced. In this case, it is possible to speed up subsequent processing.

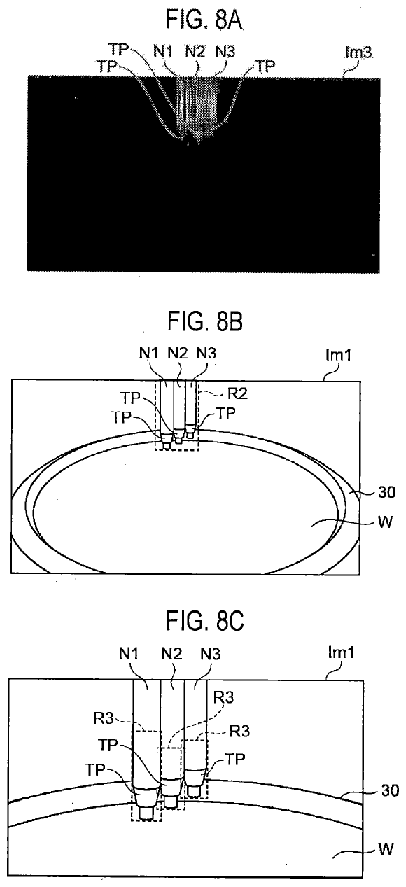

Next, the controller Ctr performs an edge extraction on the difference image (see step S13 in FIG. 6). For example, the controller Ctr uses a well-known method to detect points in the difference image where brightness is changed sharply based on a brightness value of the difference image. As a result, an extracted image Im3 (see FIG. 8A) is obtained by performing an edge extraction process on the difference image.

During this edge extraction process, a removal filter may be used that leaves mainly longitudinal edges extending along a longitudinal direction of the image in the extracted image Im3, while not leaving transverse edges extending along a transverse direction in the extracted image Im3 among the extracted edges. By using such a removal filter, the extracted image Im3 from which the transverse edges have been removed can be obtained (see step S13 in FIG. 6).

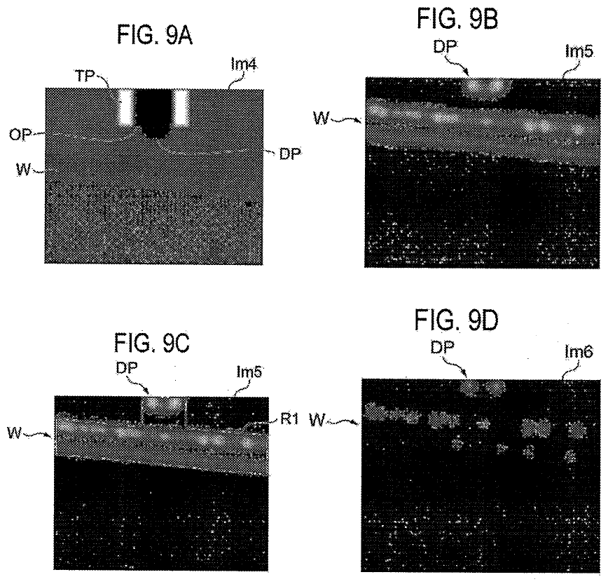

Now, the removal filter will be considered based on a difference image Im4 illustrated in FIG. 9A. In the difference image Im4, a droplet DP hangs from the injection port OP of the nozzle N, and the droplet DP is captured in proximity to an outer peripheral edge of the substrate W. When the edge extraction process is performed on this difference image Im4 without using the removal filter, an extracted image Im5 as illustrated in FIG. 9B is obtained. In this case, the outer peripheral edge of the substrate W remains as a transverse edge, so that there is a case in which a region R1 where the droplet DP and the substrate W are joined is erroneously detected as a “droplet,” as illustrated in FIG. 9C. On the other hand, when the edge extraction process is performed on the difference image Im4 using the removal filter, an extracted image Im6 as illustrated in FIG. 9D is obtained. In the extracted image Im6, a transverse edge corresponding to the outer peripheral edge of the substrate W is largely removed, so that only the droplet DP is detected as a “droplet.”

The removal filter may be set, for example, so that a response is maximum when an edge angle is vertical and minimum when the edge angle is horizontal. In the removal filter, a response threshold value for determining an edge as a transverse edge may be set by a prior experimentation to a value that removes an erroneously detected object (e.g., the outer peripheral edge of the substrate W).

Next, the controller Ctr detects positions of the tip end portions TP of the multiple nozzles N1 to N3 based on the extracted image Im3 (see step S14 in FIG. 6). This overall position detection process may be performed, for example, by comparing an edge of the extracted image Im3 with edges of multiple reference images included in a feature map. Each of the multiple reference images constituting the feature map may be an extracted image obtained by performing the edge extraction process on previously captured images of the nozzles N1 to N3 for each position of the arm Am. Through the overall position detection process, a region R2 surrounding the multiple nozzles N1 to N3 is set (see FIG. 8B).

Next, the controller Ctr detects the position of the tip end portion TP of each of the nozzles N1 to N3 within the region R2 of the extracted image Im3 (see step S15 in FIG. 6). This individual position detection process may be performed, for example, by comparing edges within the region R2 of the extracted image Im3 with edges of a template image (so-called template matching). The template image may be an extracted image obtained by capturing an image of the tip end portion TP of one nozzle N in advance and then performing the edge extraction process on that captured image. When the nozzle unit 42 includes multiple nozzles N, the individual position detection process may be performed as many times as the number of nozzles N. The individual position detection process sets a region R3 surrounding each of the nozzles N1 to N3 (see FIG. 8C). Further, although a process for one nozzle N will be described below, similar processes are performed for the remaining nozzles N.

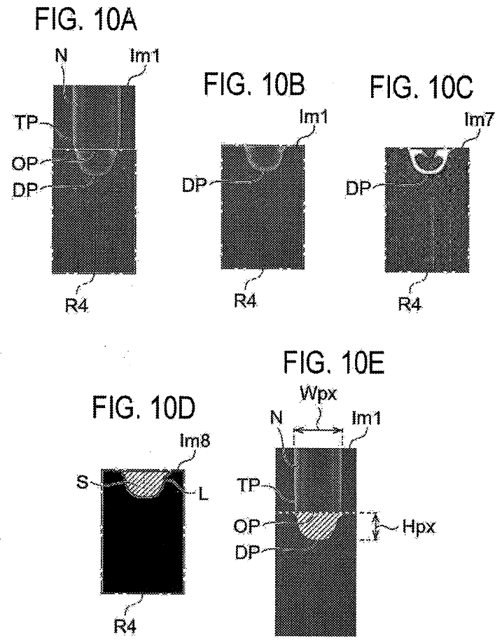

Next, the controller Ctr detects the injection port OP of the nozzle N in the region R3 of the currently captured image Im1, and sets the lower region R4 (see FIG. 10A) of a predetermined size that is in contact with the injection port OP and extends below the injection port OP (see step S16 in FIG. 6). The lower region R4 may be set, for example, to have a width slightly larger than a width of the tip end portion TP of the nozzle N and a height slightly larger than the maximum height to which the droplet DP hangs downward from the injection port OP of the nozzle N.

Next, the controller Ctr cuts out only the lower region R4 from the currently captured image Im1 (see FIG. 10B) and performs the edge extraction on the lower region R4 (see step S17 in FIG. 6). For example, the controller Ctr uses a well-known method to detect points in the lower region R4 where brightness is changed sharply, based on a brightness value of the difference image. In this way, an extracted image Im7 (see FIG. 10C) in which the lower region R4 has been subjected to the edge extraction process is obtained. In addition, before performing the edge extraction process on the lower region R4, a process of removing noise from the lower region R4 may be performed.

Next, the controller Ctr executes a process of binarizing the lower region R4. Thereafter, the controller Ctr executes a complementation process to fill in the portions of the lower region R4 that are surrounded by the edges which has been subjected to the binarization. Thus, a shape of an object in contact with the injection port OP of the nozzle N is determined, and a discrimination image Im8 for determining whether the object is a droplet DP is obtained (see FIG. 10D).

Next, the controller Ctr detects whether or not a droplet DP is hanging from the injection port OP of the nozzle N based on the extracted image Im7 (see step S18 in FIG. 6). The controller Ctr may detect the presence or absence of a droplet DP based on, for example, the shape of the object in contact with the injection port OP of the nozzle N in the extracted image Im7.

A determination of a droplet DP as to whether the object is a droplet DP may be made by determining at least one of a circularity or an aspect ratio of the shape of the object. The circularity can be calculated, for example, using Equation (1), where L is a perimeter of the object (see FIG. 10D) and S is an area of the object (see FIG. 10D).

$$Circularity = 4 π S / {L}^{2} \qquad ( 1 )$$

According to Equation 1, as the circularity is closer to 0, the object is closer to a straight line, and as the circularity is closer to 1, the object is closer to a perfect circle. The controller Ctr may determine that the object is a droplet DP, for example, when the circularity is 0.1 or greater.

The aspect ratio can be calculated, for example, using Equation (2) where a rectangle circumscribing the object is set with a long side of the rectangle being w and a height being h.

$$Aspect ratio = w / h \qquad ( 2 )$$

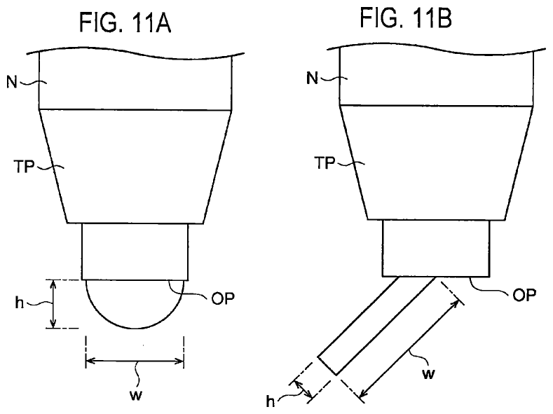

According to Equation (2), as the aspect ratio is smaller, the object is more likely to a droplet DP (see FIG. 11A), and as the aspect ratio is larger, the object is more likely to an object other than a droplet DP, which overlaps with the injection port OP of the nozzle N (see FIG. 11B). The controller Ctr may determine that the object is a droplet DP, for example, when the aspect ratio is 5 or less. Further, when using both the circularity and aspect ratio indicators, the controller Ctr may determine that the object is a droplet DP, for example, when the circularity is 0.1 or greater and the aspect ratio is 5 or less.

When it is determined that the object in contact with the injection port OP of the nozzle N is a droplet DP, the controller Ctr calculates an actual height H [mm] of the droplet DP (see FIG. 10E) (see step S19 in FIG. 6). The actual height H of the droplet DP can be calculated, for example, using Equation (3) where Wr is an actual width of the tip end portion TP of the nozzle N [mm], Wpx is a width of the tip end portion TP of the nozzle N in the currently captured image Im1 [pixel], and Hpx is a height of the droplet DP in the currently captured image Im1 [pixel].

$$H = Hpx \times Wr / Wpx \qquad ( 3 )$$

By converting the number of pixels in the image (pixels) to length (mm) in SI units as in Equation (3), it is also possible to quantitatively calculate heights of droplets in adjacent other nozzles from the image.

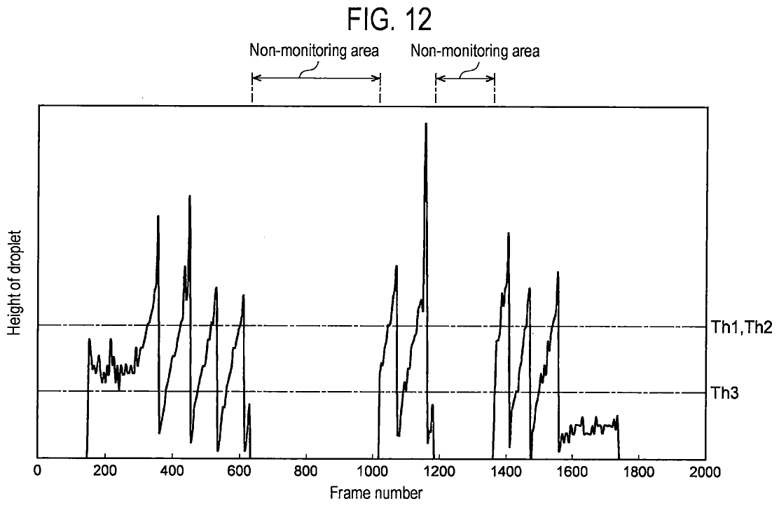

Next, the controller Ctr determines whether or not there is an abnormality based on the calculated actual height H of the droplet DP (see step S20 in FIG. 6). For example, when the height H is equal to or greater than a predetermined threshold value Th1 (predetermined value) (see FIG. 12), the controller Ctr may determine that there is a growth in the droplet DP associated with a continued supply of the processing liquid to the nozzle N.

In the liquid leakage detection process, the above process is repeatedly performed while the nozzle N is moving at the processing position. An example of the change in the height H calculated for each frame at this time is shown in FIG. 12. On the other hand, when the nozzle N reaches the standby position, the liquid leakage detection process is terminated and the process proceeds to step S4.

In step S20, whether or not an abnormality exists may be determined based on the height H calculated for each of the captured images before and after one frame. For example, when a height calculated for a captured image of a predetermined frame is H1 and a height calculated for a captured image of a next frame (next captured image) is H2, it may be determined that a droplet DP that has grown to a certain extent has fallen from the injection port OP of the nozzle N when the height H1 is equal to or greater than a predetermined threshold value Th2 (first value) (see FIG. 12) and the height H2 is equal to or less than a predetermined threshold value Th3 (second value) (see FIG. 12) which is smaller than the threshold value Th2. Further, the threshold value Th2 may be the same as the threshold value Th1.

### [Operation]

In a process of manufacturing a semiconductor device or the like, various processing liquids are supplied to the substrate W to process the substrate W. The processing liquids are supplied from the supplier 40 to the nozzle N and injected downward toward the substrate W from the injection port OP provided at the tip end portion TP of the nozzle N. On the other hand, when the supply of the processing liquids from the supplier 40 to the nozzle N is stopped, the injection of the processing liquids from the injection port OP of the nozzle N also stops. However, due to an abnormality in the supplier 40 (e.g., valve deterioration) or the like, the supply of the processing liquids to the nozzle N may continue slightly even though the supply of the processing liquids from the supplier 40 to the nozzle N has been stopped. In this case, a droplet DP may grow at the injection port OP of the nozzle N, and the droplet DP of the processing liquid may fall from the nozzle N. When the droplet DP of the processing liquid falls from the nozzle N onto the substrate W by the liquid leakage from the nozzle N, it may lead to a defect in the substrate W.

Therefore, in the above example, whether or not a droplet DP is hanging from the injection port OP of each nozzle N is determined based on the currently captured image Im1 of the nozzles N1 to N3. Further, when a droplet DP is hanging, the height H of the droplet DP is calculated, and whether or not an abnormality exists is determined based on the height H. For example, when the height H (growth degree) of the droplet DP at the injection port OP of the nozzle N is relatively small, it can be determined that no abnormality exists in the supplier 40, considering that the supply of the processing liquids by the supplier 40 is stopped, and thus the supply of the processing liquids to the nozzle N is stopped. On the other hand, when the height H (growth degree) of the droplet DP at the injection port OP of the nozzle N is relatively large, it can be determined that an abnormality exists in the supplier 40, considering that even though the supply of the processing liquids by the supplier 40 is stopped, the supply of the processing liquids to the nozzle N continues. In this way, according to the above example, it is possible to simultaneously detect abnormalities associated with a liquid leakage from the nozzle N for multiple nozzles N1 to N3.

According to the above example, when the height H of the droplet DP is equal to or greater than the threshold value Th1, it is determined that an abnormality exists. Therefore, it is possible to more accurately determine the liquid leakage from the nozzle N.

According to the above example, whether or not an abnormality exists is determined based on the heights H1 and H2 calculated for the respective captured images before and after one frame. That is, when height H1≥threshold value Th2 and height H2≤threshold value Th3, it is determined that the droplet DP has fallen from the injection port OP of the nozzle N. When height H1≥threshold value Th2, it is estimated that the droplet DP has grown to a certain size at the injection port OP of the nozzle N. Then, when height H2≤threshold value Th3, it is estimated that the height H of the droplet DP has suddenly decreased from the certain size. Therefore, when the above conditions are met, it can be determined that the droplet DP has fallen from the nozzle N. Therefore, according to the above example, it is possible to accurately determine the fall of the droplet DP from the nozzle N using the above conditions.

According to the above example, the position of the tip end portion TP of the nozzle Nis detected by performing the edge extraction based on the currently captured image Im1. Therefore, a boundary of the tip end portion TP of the nozzle N becomes clear in the currently captured image Im1. Accordingly, it is possible to more accurately determine a position of the injection port OP of the nozzle N in the currently captured image Im1.

According to the above example, the tip end portion TP of the nozzle N is detected by performing the edge extraction process on the difference image. Therefore, objects that have not moved between the currently captured image Im1 and the previously captured image Im2 are removed from the difference image. Therefore, when the nozzle Nis moving, by the edge extraction process, it is possible to more accurately extract the boundary of the tip end portion TP of the nozzle N.

According to the above example, the mask region Rm is set below the injection port OP of the nozzle N in the previously captured image Im2 so as to be in contact with the injection port OP. In this case, when the difference between the currently captured image Im1 and the previously captured image Im2 is taken, pixel values of a region in the currently captured image Im1 corresponding to the mask region Rm remain unchanged in the difference image. Therefore, regardless of whether the nozzle N is moving or stationary, when a droplet DP hangs from the injection port OP of the nozzle N, the droplet DP remains in the difference image. Accordingly, in the difference image, objects that are not moving between the currently captured image Im1 and the previously captured image Im2 are removed. Thus, the droplet DP at the injection port OP of the nozzle N remains, thereby making it possible to detect the droplet DP more accurately.

Since the nozzle N and the droplet DP extend in the up-down direction in the currently captured image Im1, when the currently captured image Im1 is subjected to the edge extraction process, the nozzle N and the droplet DP are detected as longitudinal edges extending in the longitudinal direction. On the other hand, in the currently captured image Im1, contours of objects other than the nozzle N and the droplet DP (e.g., the substrate W or other device) may extend in the transverse direction. In this case, when the currently captured image Im1 is subjected to the edge extraction process, the contours are detected as transverse edges extending in the transverse direction. When the longitudinal edges of the nozzle N or the droplet DP intersect with or are close to the transverse edges, the nozzle N or the droplet DP may not be detected correctly. However, according to the above example, when the edges detected by the edge extraction process are transverse edges extending in the transverse direction, the transverse edges are removed. Thus, it is possible to detect the nozzle N and the droplet DP with high accuracy.

Incidentally, in the currently captured image Im1, the contour of the object other than the nozzle N or the droplet DP may appear to intersect with the injection port OP of the nozzle N. In this case, there is a concern that the contour may be erroneously detected as the droplet DP. However, according to the above example, whether or not the droplet DP is hanging from the injection port OP is detected based on the shape of the object in contact with the injection port OP of the nozzle N. Therefore, it is less likely to erroneously detect an object other than the droplet DP as a droplet DP. Accordingly, it is possible to detect the droplet DP with higher accuracy.

Incidentally, the droplet DP hanging from the injection port OP generally has a substantially semicircular shape. Therefore, according to the above example, whether or not a droplet DP is hanging from the injection port OP is detected based on at least one of the circularity or the aspect ratio of the object in contact with the injection port OP of the nozzle N. Therefore, it is possible to more accurately detect whether or not the object in contact with the injection port OP is a droplet DP.

According to the above example, the tip end portion TP is detected by comparing the currently captured image Im1 with a reference image of the tip end portion TP captured in advance. Therefore, the tip end portion TP is detected based on whether or not it matches the reference image, and thus it is possible to detect the tip end portion TP extremely efficiently.

### [Modifications]

It should be noted that the disclosure in the present specification is exemplary in all respect and not restrictive. Various omissions, substitutions, modifications, and the like may be made to the above examples without departing from the scope and spirit of the appended claims.

(1) In the liquid leakage detection process, as illustrated in FIG. 12, a non-monitoring area may be set in which an image of the nozzle N is not captured. In other words, the height H is not calculated in the non-monitoring area.

The non-monitoring area may be set in advance to, for example, a portion of a movement path of the arm Am where at least two of the nozzles N1 to N3 overlap with each other when viewed from the capturer 50 so that it is impossible to individually detect the tip end portions TP of the nozzles N. In this case, while the arm Am is moving, steps S11 to S20 are executed during the period in which the nozzles N1 to N3 image-captured by the capturer 50 do not overlap with each other.

The non-monitoring area may be set in advance, for example, to a portion of the movement path of the arm Am where the nozzle N and an inner peripheral edge of the cup 30 overlap with each other when viewed from the capturer 50 so that it is impossible to detect the tip end portion TP of the nozzle N. The non-monitoring area may be set in advance, for example, to a portion of the movement path of the arm Am where an object other than the nozzle N (e.g., the arm Am) is reflected on a surface of the substrate W and overlaps with the nozzle N when viewed from the capturer 50 so that it is impossible to detect the tip end portion TP of the nozzle N.

In this case, when the tip end portion TP of the nozzle N is hidden and cannot be detected, no process is performed. Therefore, it is possible to efficiently utilize computational resources.

(2) In the liquid leakage detection process, the controller Ctr may determine whether at least two of the nozzles N1 to N3 image-captured by the capturer 50 overlap with each other. In this case, the controller Ctr may execute steps S11 to S20 during the period in which it is determined that the nozzles do not overlap with each other. In this way, it is possible to efficiently utilize computational resources.

The determination as to whether at least two of the nozzles N1 to N3 image-captured by the capturer 50 overlap with each other may be made based on a distance between the edges of the nozzles N in the extracted image Im3 obtained from the currently captured image Im1. For example, when the distance between the edges of the nozzles N in the extracted image Im3 obtained from the currently captured image Im1 is smaller than a predetermined threshold value, it may be determined that the nozzles N overlap with each other. In this case, it is possible to more accurately determine whether at least two of the multiple nozzles N1 to N3 overlap with each other based on the distance between the edges of the tip end portions TP.

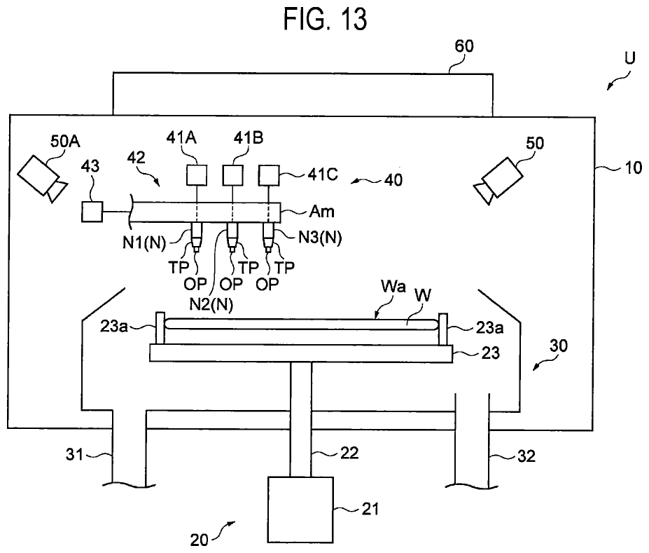

(3) As illustrated in FIG. 13, the liquid processing unit U may further include a capturer 50A. The image captured by the capturer 50A is processed in the same manner as in steps S11 to S20.

The capturer 50A is disposed at a position different from a position of the capturer 50 within the housing 10. The capturer 50A may be disposed, for example, at a position where it can capture an image of the nozzle N from a direction different from a direction of capturing by the capturer 50. The capturer 50A may be disposed, for example, at a position where it can capture the nozzle N located in the non-monitoring area of the capturer 50. In this case, even when the multiple nozzles N1 to N3 overlap with each other in the currently captured image Im1 of the capturer 50, an image in which the multiple nozzles N1 to N3 do not overlap with each other is obtained by the capturer 50A. Therefore, it is possible to determine whether or not there is an abnormality for the entire process in which the nozzle N moves by using the capturers 50 and 50A.

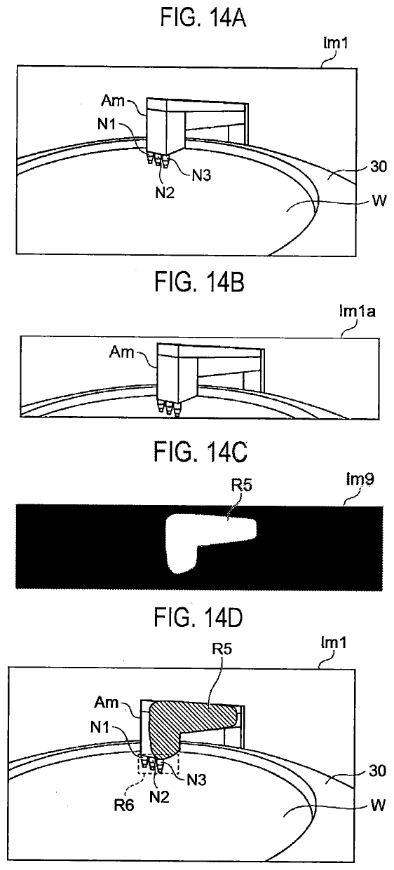

(4) Instead of the process of steps S11 to S14, a region surrounding the plurality of nozzles N1 to N3 may be set by another method. First, the controller Ctr instructs the capturer 50 to capture moving images of the nozzles N1, N2 and N3 and the arm Am at the processing position (see FIG. 14A). Next, the controller Ctr cuts out an upper portion of a currently captured image Im1 captured by the capturer 50, in which the arm Am is reflected, from the currently captured image Im1 to generate a cut-out image Im1a (see FIG. 14B).

Next, the controller Ctr binarizes the cut-out image Im1a to generate a binarized image Im9 (see FIG. 14C). As a result, in the binarized image Im9, a partial region R5 of the arm Am, which is white or gray, is displayed in white, and the remaining region is displayed in black. The controller Ctr may binarize the cut-out image Im1a based on a brightness value.

Next, the controller Ctr determines a position of the arm Am in the currently captured image Im1 based on at least one of an area or a shape of the region R5. Thereafter, the controller Ctr sets a predetermined region in the currently captured image Im1 below the region determined to be the arm Am, as a region R6 surrounding the multiple nozzles N1 to N3 (see FIG. 14D).

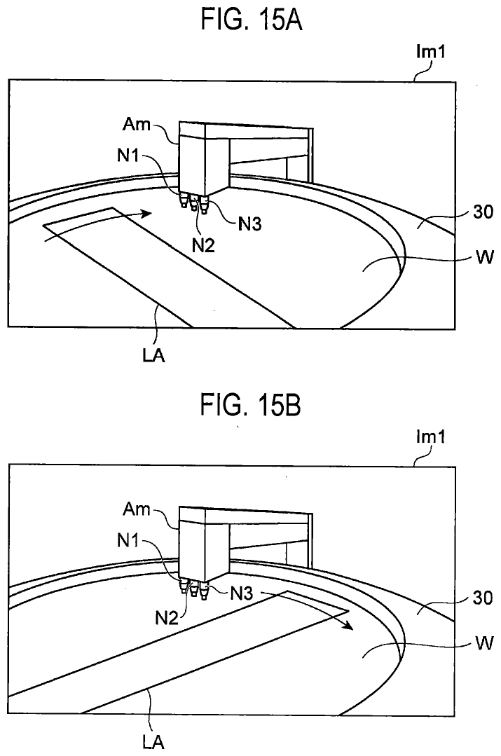

(5) Incidentally, when the capturer 50 captures the nozzles N1 to N3, light from inside or outside the housing 10 may be reflected on the upper surface Wa of the substrate W. Typically, during the capturing, the substrate W held by the holder 23 is rotated by the driver 20. Therefore, as illustrated in FIGS. 15A and 15B, a position of a region LA where light is reflected on the upper surface Wa of the substrate W is changed relative to the nozzle N during the capturing. In addition, although the region LA is shown as a rectangle in FIGS. 15A and 15B by way of example, in reality, the region LA may take various shapes based on various factors such as a structure of elements and the like formed on the upper surface Wa of the substrate W and a position of a light source relative to the substrate W.

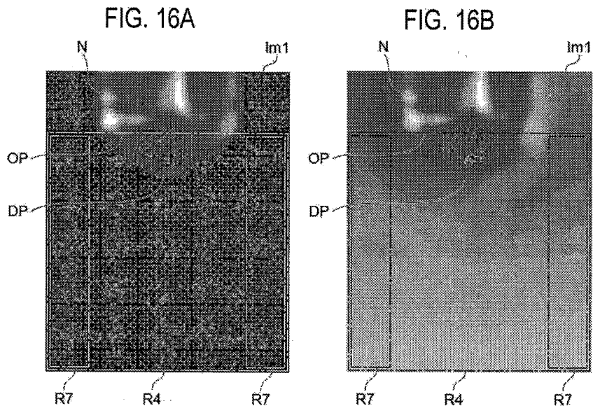

As the position of the region LA is changed relative to the nozzle N, when the region LA is located in a vicinity of the injection port OP of the nozzle N or when the region LA overlaps with the injection port OP, a brightness value of the captured image including the injection port OP increases. Therefore, in the captured image, there is a case in which the brightness of the injection ports OP of the nozzles N1 to N3 and their surroundings become closer. That is, when the region LA is spaced apart from the injection port OP, as illustrated in FIG. 16A, a brightness of pixels corresponding to the tip end portion TP of the nozzle N, the injection port OP, and the droplet DP in the currently captured image Im1 tends to be high, while a brightness of pixels other than these pixels tends to be low. In contrast, when the region LA is located in a vicinity of the injection port OP or overlaps with the injection port OP, as illustrated in FIG. 16B, the brightness of pixels not only at the tip end portion TP of the nozzle N, the injection port OP, and the droplet DP, but also in their vicinity tends to be high.

Therefore, the controller Ctr may determine whether a brightness value of the currently captured image Im1 exceeds a predetermined threshold value Th4. When the brightness value of the currently captured image Im1 exceeds the threshold value Th4, the controller Ctr may determine that the currently captured image Im1 is a high-brightness image. The controller Ctr may execute the liquid leakage detection process according to the above example based on an image other than the high-brightness image among the currently captured images Im1.

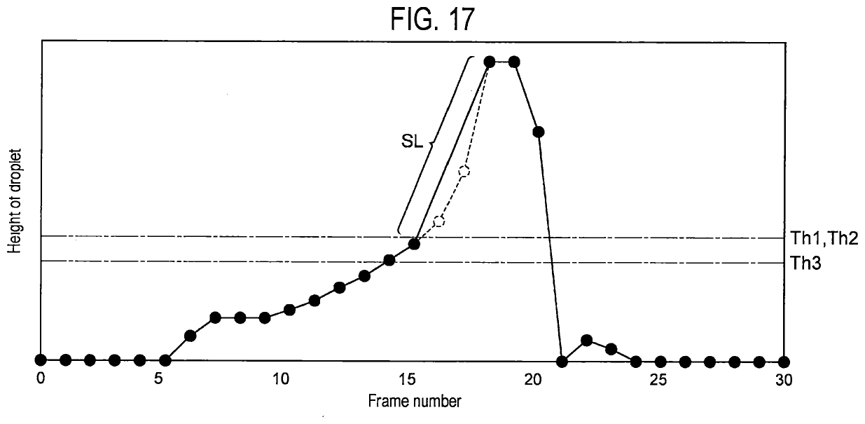

The controller Ctr may determine that the currently captured image Im1 illustrated in FIG. 16A is not a high-brightness image. In this case, the controller Ctr executes the liquid leakage detection process according to the above example using the currently captured image Im1 illustrated in FIG. 16A. On the other hand, the controller Ctr may determine that the currently captured image Im1 illustrated in FIG. 16B is a high-brightness image. In this case, the controller Ctr does not execute the liquid leakage detection process according to the above example on the currently captured image Im1 illustrated in FIG. 16B. That is, as illustrated in FIG. 17, when the captured images in frames 16 and 17 are high-brightness images, a height of a droplet DP based on these images is not calculated (see dashed circles in FIG. 17). Therefore, in the graph illustrated in FIG. 17, since the detection of hanging of the droplet DP is skipped in frames 16 and 17, the height of the droplet DP in frame 15 and the height of the droplet DP in frame 18 are connected by a straight line SL. Therefore, since it is possible to avoid erroneous detection of hanging of the droplet DP from the injection port OP, it is possible to more accurately determine whether or not there is an abnormality in the supplier 40.

In addition, when a brightness value of a predetermined set region of the currently captured image Im1 exceeds the threshold value Th4, the controller Ctr may determine that the currently captured image Im1 is a high-brightness image. The set region may be the lower region R4, as illustrated in FIGS. 16A and 16B. As described above, the lower region R4 may be the region of the predetermined size that is adjacent to the injection port OP and extends below the injection port OP. In this case, it is possible to simplify a calculation process compared to a case where a high-brightness image is determined based on brightness values of all pixels in the currently captured image Im1.

As illustrated in FIGS. 16A and 16B, the set region may be an outer region R7 located below the position of the injection port OP and outside the injection port OP in a width direction of the injection part OP. In this case, light reflected from a droplet DP hanging from the injection port OP is excluded from the determination of whether the currently captured image Im1 is a high-brightness image. Therefore, it is possible to more accurately determine whether the currently captured image Im1 is a high-brightness image.

When an average value of brightness values of a plurality of pixels in the currently captured image Im1 exceeds the threshold value Th4, the controller Ctr may determine that the currently captured image Im1 is a high-brightness image. For example, when an average value of brightness values of the respective pixels in the set region which is set in the currently captured image Im1 exceeds the threshold value Th4, the controller Ctr may determine that the currently captured image Im1 is a high-brightness image. In this case, even when the pixels constituting the currently captured image Im1 include a particularly extremely dark or extremely bright pixel, it is possible to more accurately determine whether the currently captured image Im1 is a high-brightness image.

### OTHER EXAMPLES

### Example 1

One example of a substrate processing apparatus includes: a rotary holder configured to hold and rotate a substrate; an arm configured to hold a plurality of nozzles; a driver configured to drive the arm so that the plurality of nozzles move between a standby position outside the substrate held by the rotary holder and a processing position above the substrate held by the rotary holder; a capturer configured to capture an image of the plurality of nozzles; a supplier configured to supply processing liquids to each of the plurality of nozzles; and a controller. The controller is configured to control the supplier and the capturer to perform a first process of causing the capturer to capture images of the plurality of nozzles located at the processing position when the supply of the processing liquids to the plurality of nozzles is stopped, a second process of detecting tip end portions of the plurality of nozzles based on the images captured in the first process, a third process of detecting whether or not a droplet is hanging from an injection port of each of the tip end portions detected in the second process based on the images captured in the first process, a fourth process of calculating a height of the droplet when the hanging droplet is detected in the third process, and a fifth process of determining whether or not an abnormality exists based on the height of the droplet calculated in the fourth process.

In a process of manufacturing a semiconductor device or the like, various processing liquids are supplied to the substrate to process the substrate. The processing liquids are supplied from the supplier to the nozzle and injected downward toward the substrate from the injection port provided at the tip end portion of the nozzle. Meanwhile, when the supply of the processing liquids from the supplier to the nozzle is stopped, the injection of the processing liquids from the injection port of the nozzle also stops. However, due to an abnormality in the supplier or the like, the supply of the processing liquids to the nozzle may continue slightly even though the supply of the processing liquids from the supplier to the nozzle has been stopped. In this case, a droplet may grow at the injection port of the nozzle, and the droplet of the processing liquid may fall from the nozzle. When the droplet of the processing liquid falls from the nozzle onto the substrate by the liquid leakage from the nozzle, it may lead to a defect in the substrate.

Therefore, in the apparatus of Example 1, whether or not a droplet is hanging from the injection port of each nozzle is determined based on the captured image of the plurality of nozzles. Further, when a droplet is hanging, the height of the droplet is calculated, and whether or not an abnormality exists is determined based on the height. For example, when the height (growth degree) of the droplet at the injection port of the nozzle is relatively small, it can be determined that no abnormality exists in the supplier, considering that the supply of the processing liquids by the supplier is stopped, and thus the supply of the processing liquids to the nozzle N is stopped. On the other hand, when the height (growth degree) of the droplet at the injection port of the nozzle is relatively large, it can be determined that an abnormality exists in the supplier, considering that even though the supply of the processing liquids by the supplier is stopped, the supply of the processing liquids to the nozzle continues. In this way, according to the apparatus of Example 1, it is possible to simultaneously detect abnormalities associated with a liquid leakage from the nozzle for multiple nozzles.

### Example 2

In the substrate processing apparatus of Example 1, the fifth process may include determining that the abnormality exists when the height of the droplet is equal to or greater than a predetermined value. In this case, it is possible to more accurately determine the liquid leakage form the nozzle.

### Example 3

In the substrate processing apparatus of Example 1 or Example 2, the capturer may be configured to capture moving images of the plurality of nozzles, and the fifth process may include determining that the droplet has fallen when the height of the droplet, which has been subjected to the second process to the fourth process based on one captured image, is equal to or greater than a first value and when the height of the droplet, which has been subjected to the second process to the fourth process based on a subsequently captured image which is a frame following the one captured image, is equal to or less than a second value which is smaller than the first value. As in Example 3, when it is detected that the height of the droplet has suddenly decreased from a certain size, it can be determined that the droplet has fallen from the nozzle. Therefore, according to Example 3, it is possible to accurately determine whether the droplet has fallen from the nozzle.

### Example 4

In the substrate processing apparatus of any one of Examples 1 to 3, the second process may include detecting the tip end portions by an edge extraction process. In this case, by performing the edge extraction process on the captured images, a boundary of the tip end portion of the nozzle becomes clear in the captured images. Therefore, it is possible to more accurately determine a position of the injection port of the nozzle in the captured images.

### Example 5

In the substrate processing apparatus of Example 4, the capturer may be configured to capture moving images of the plurality of nozzles, and the second process may include detecting the tip end portions by performing the edge extraction process on a difference image obtained by taking a difference between one captured image and a previously captured image, which is a frame immediately before the one captured image. In this case, objects that have not moved between the one captured image and the previously captured image are removed from the difference image. Therefore, when the nozzles are moving, it is possible to more accurately extract the boundary of the tip end portion of the nozzle by the edge extraction process.

### Example 6

In the substrate processing apparatus of Example 5, the second process may include setting a mask region below the injection port of each of the tip end portions in the previously captured image so as to be in contact with the injection port. In this case, when the difference between the one captured image and the previously captured image is taken, pixel values of a region in the one captured image corresponding to the mask region remain unchanged in the difference image. Therefore, regardless of whether the nozzle is moving or stationary, when a droplet hangs from the injection port of the nozzle, the droplet remains in the difference image. Accordingly, in the difference image, objects that are not moving between the one captured image and the previously captured image are removed. Thus, the droplet at the injection port of the nozzle remains, thereby making it possible to detect the droplet more accurately.

### Example 7

In the substrate processing apparatus of any one of Examples 4 to 6, the second process may include removing a transverse edge when edges detected by the edge extraction process is the transverse edge extending along a transverse direction. Since the nozzle and the droplet extend in the up-down direction in the captured image, when the captured image is subjected to the edge extraction process, the nozzle and the droplet are detected as longitudinal edges extending in a longitudinal direction. Meanwhile, in the captured image, contours of objects other than the nozzle or the droplet (e.g., a substrate or other device) may extend in the transverse direction. In this case, when the captured image is subjected to the edge extraction process, the contours are detected as transverse edges extending in the transverse direction. When the longitudinal edges of the nozzle or the droplet intersect with or are close to the transverse edges, the nozzle or the droplet may not be detected correctly. However, according to Example 7, since the transverse edges are removed, it is possible to accurately detect the nozzle or the droplet.

### Example 8

In the substrate processing apparatus of any one of Examples 1 to 7, the third process may include detecting whether or not the droplet is hanging from the injection port of each of the tip end portions based on a shape of an object in contact with the injection port of each of the tip end portions. In the captured image, the contour of the object other than the nozzle or the droplet may appear to intersect with the injection port of the nozzle. In this case, there is a concern that the contour may be erroneously detected as the droplet. However, according to Example 8, whether or not the droplet is hanging from the injection port of the tip end portion is detected based on the shape of the object in contact with the injection port of the tip end portion. Therefore, it is less likely to erroneously detect an object other than the droplet as a droplet. Accordingly, it is possible to detect the droplet with higher accuracy.

### Example 9

In the apparatus of Example 8, the third process may include detecting whether or not a droplet is hanging from the injection port of each of the tip end portions based on at least one of a circularity or an aspect ratio of the object in contact with the injection port of each of the tip end portions. A droplet hanging from the injection port generally has a substantially semicircular shape. Therefore, as in Example 9, by using at least one of the indicators of the circularity or the aspect ratio, it is possible to more accurately detect whether the object in contact with the injection port of each of the tip end portions is a droplet.

### Example 10

In the substrate processing apparatus of any one of Examples 1 to 9, the second process may include detecting the tip end portions by comparing the images captured in the first process with a reference image of the tip end portion captured in advance. In this case, the tip end portion is detected based on whether or not the captured images match the reference image, and thus it is possible to detect the tip end portions extremely efficiently.

### Example 11

In the substrate processing apparatus of any one of Examples 1 to 10, the controller may be configured to perform the first process to the fifth process during a period in which the plurality of nozzles image-captured by the capturer do not overlap with each other while the arm is moved by the driver. Meanwhile, when the plurality of nozzles overlap with each other in the captured images (e.g., a case in which one nozzle is completely or largely hided by another nozzle), there is a possibility that the overlapped nozzle cannot be detected. Therefore, even when a process of detecting the nozzle is executed based on the captured image, the process may be wasted. However, according to Example 11, the first process to the fifth process are executed during the period in which the plurality of nozzles do not overlap with each other. Therefore, it is possible to efficiently use computational resources.

### Example 12

In the apparatus of Example 11, the controller may be configured to further perform a sixth process of determining whether at least two of the plurality of nozzles image-captured by the capturer overlap with each other while the arm is moved by the driver, and may be configured to perform the first process to the fifth process during a period in which it is determined that the plurality of nozzles do not overlap with each other in the sixth process. In this case, the same effects as those of Example 11 are obtained.

### Example 13

In the apparatus of Example 12, the second process may include detecting the tip end portions by an edge extraction process, and the sixth process may include determining whether at least two of the plurality of nozzles image-captured by the capturer overlap with each other based on a distance between the edges of the tip end portions. In this case, it is possible to more accurately determine whether at least two of the plurality of nozzles overlap with each other based on the distance between the edges of the tip end portions.

### Example 14

The substrate processing apparatus of any one of Examples 1 to 13 may further include an additional capturer configured to capture images of the plurality of nozzles and disposed at a position different from a position of the capturer, and the controller may be configured to control the supplier and the additional capturer to perform a sixth process of causing the additional capturer to capture images of the plurality of nozzles located at the processing position when the processing liquids are not being injected from the plurality of nozzles, a seventh process of detecting the tip end portions of the plurality of nozzles based on the images captured in the sixth process, an eighth process of detecting whether or not the droplet is hanging from the injection port of each of the tip end portions detected in the seventh process based on the images captured in the sixth process, a ninth process of calculating the height of the droplet when the hanging droplet is detected in the eighth process, and a tenth process of determining whether or not the abnormality exists based on the height of the droplet calculated in the ninth process. In this case, even when the plurality of nozzles overlap with each other in the images captured by the capturer, captured images in which the plurality of nozzles do not overlap with each other is obtained by the additional capturer. Therefore, by the capturer and the additional capturer, it is possible to determine whether or not an abnormality exists for all processes in which the nozzles move.

### Example 15

In the substrate processing apparatus of any one of Examples 1 to 14, the controller may be configured to further perform the sixth process of, when a brightness value of each of the images captured in the first process exceeds a predetermined threshold value, determining that each of the captured images is a high-brightness image, and the third process may include detecting whether or not the droplet is hanging from the injection port of each of the tip end portions detected in the second process, based on an image other than the high-brightness image among the images captured in the first process. Incidentally, when the brightness value of the captured image increases due to a light reflection on an upper surface of the substrate or the like, the brightnesses of the injection port of the nozzle and its surroundings become close to each other. Therefore, it may be difficult to determine a location of the injection port of the nozzle in the captured image. However, according to Example 15, for the high-brightness image in which the brightness value of the captured image exceeds the predetermined threshold value, a droplet hanging from the injection port is not detected. In other words, for the high-brightness image, the detection of the droplet hanging from the injection port is skipped. Therefore, since erroneous detection of the droplet hanging from the injection port can be avoided, it is possible to more accurately determine whether an abnormality exists in the supplier.

### Example 16

In the substrate processing apparatus of Example 15, the sixth process may include determining, when an average value of the brightness values of a plurality of pixels in each of the images captured in the first process exceeds the threshold value, that each of the captured images is a high-brightness image. In this case, whether each of the captured images is a high-brightness image is determined based on the average value of the brightness values of the plurality of pixels. Therefore, even when the pixels constituting the captured image include a peculiarly extremely dark or extremely bright pixel, it is possible to more accurately determine whether the captured image is a high-brightness image.

### Example 17

In the substrate processing apparatus of Example 15 or Example 16, the sixth process may include determining, when a brightness value of a predetermined set region which is set in each of the images captured in the first process exceeds the threshold value, that each of the captured images is a high-brightness image, and the set region may be a region of each of the captured images below a position of the injection port. Incidentally, a droplet hanging from the injection port of the nozzle exists below the injection port. Therefore, as in Example 17, by determining whether the brightness value exceeds the threshold value only for the region of each of the captured images, which is below the position of the injection port, it is possible to simplify a calculation process compared to determining whether each of the captured images is a high-brightness image based on the brightness values of all pixels.

### Example 18

In the substrate processing apparatus of Example 17, the set region may be a region of each of the captured images that is below the position of the injection port and outside the injection port in a width direction of the injection port. In this case, light reflected from a droplet hanging from the injection port is excluded from the determination of whether each of the captured images is a high-brightness image. Therefore, it is possible to more accurately determine whether each of the captured images is a high-brightness image.

### Example 19

One example of a substrate processing method includes: a first step of capturing images of a plurality of nozzles held by an arm by a capturer when the plurality of nozzles are positioned at a processing position above a substrate held by a rotary holder and a supply of processing liquids to the plurality of nozzles is stopped, a second step of detecting tip end portions of the plurality of nozzles based on the images captured in the first step, a third step of detecting whether or not a droplet is hanging from an injection port of each of the tip end portions detected in the second step based on the images captured in the first step, a fourth step of calculating a height of the droplet when the hanging droplet is detected in the third step, and a fifth step of determining whether an abnormality exists based on the height of the droplet calculated in the fourth step. In this case, the same effects as those of Example 1 are obtained.

### Example 20

In the substrate processing method of Example 19, the fifth step may include determining that the abnormality exists when the height of the droplet is equal to or greater than a predetermined value. In this case, the same effects as those of Example 2 are obtained.

### Example 21

In the substrate processing method of Example 19 or Example 20, the second step may include detecting the tip end portions by an edge extraction process. In this case, the same effects as those of Example 4 are obtained.

### Example 22

In the substrate processing method of any one of Examples 19 to 21, the third step may include detecting whether or not the droplet is hanging from the injection port of each of the tip end portions based on a shape of an object in contact with the injection port of each of the tip end portions. In this case, the same effects as those of Example 8 are obtained.

### Example 23

In the substrate processing method of any one of Examples 19 to 22, the first step to fifth step may be performed during a period in which the plurality of nozzles image-captured by the capturer do not overlap with each other while the arm is moved. In this case, the same effects as those of Example 11 are obtained.

### Example 24

An example of a non-transitory computer-readable recording medium storing a substrate processing program causes, by computer, a substrate processing apparatus to perform the substrate processing method of any one of Examples 19 to 23. In this case, the same effects as those of the method of Example 19 are obtained.

According to the substrate processing apparatus, substrate processing method, and recording medium of the present disclosure, it is possible to simultaneously detect abnormalities associated with a liquid leakage from a nozzle for a plurality of nozzles.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a rotary holder configured to hold and rotate a substrate;
an arm configured to hold a plurality of nozzles;
a driver configured to drive the arm so that the plurality of nozzles move between a standby position outside the substrate held by the rotary holder and a processing position above the substrate held by the rotary holder;
a capturer configured to capture an image of the plurality of nozzles;
a supplier configured to supply processing liquids to each of the plurality of nozzles; and
a controller,
wherein the controller is configured to control the supplier and the capturer to perform:
a first process of causing the capturer to capture images of the plurality of nozzles located at the processing position when the supply of the processing liquids to the plurality of nozzles is stopped;
a second process of detecting tip end portions of the plurality of nozzles based on the images captured in the first process;
a third process of detecting whether a droplet is hanging from an injection port of each of the tip end portions detected in the second process based on the images captured in the first process;
a fourth process of calculating a height of the droplet when the hanging droplet is detected in the third process; and
a fifth process of determining whether an abnormality exists based on the height of the droplet calculated in the fourth process.

2. The substrate processing apparatus of claim 1, wherein the fifth process includes determining that the abnormality exists when the height of the droplet is equal to or greater than a predetermined value.

3. The substrate processing apparatus of claim 1, wherein the capturer is configured to capture moving images of the plurality of nozzles, and
wherein the fifth process includes determining that the droplet has fallen when the height of the droplet, which has been subjected to the second process to the fourth process based on one captured image, is equal to or greater than a first value and when the height of the droplet, which has been subjected to the second process to the fourth process based on a subsequently captured image which is a frame following the one captured image, is equal to or less than a second value which is smaller than the first value.

4. The substrate processing apparatus of claim 1, wherein the second process includes detecting the tip end portions by an edge extraction process.

5. The substrate processing apparatus of claim 4, wherein the capturer is configured to capture moving images of the plurality of nozzles, and
wherein the second process includes detecting the tip end portions by performing the edge extraction process on a difference image obtained by taking a difference between one captured image and a previously captured image, which is a frame immediately before the one captured image.

6. The substrate processing apparatus of claim 5, wherein the second process includes setting a mask region below the injection port of each of the tip end portions in the previously captured image so as to be in contact with the injection port.

7. The substrate processing apparatus of claim 4, wherein the second process includes removing a transverse edge when edges detected by the edge extraction process is the transverse edge extending along a transverse direction.

8. The substrate processing apparatus of claim 1, wherein the third process includes detecting whether the droplet is hanging from the injection port of each of the tip end portions based on a shape of an object in contact with the injection port of each of the tip end portions.

9. The substrate processing apparatus of claim 1, wherein the second process includes detecting the tip end portions by comparing the images captured in the first process with a reference image of the tip end portion captured in advance.

10. The substrate processing apparatus of claim 1, wherein the controller is configured to perform the first process to the fifth process during a period in which the plurality of nozzles image-captured by the capturer do not overlap with each other while the arm is moved by the driver.

11. The substrate processing apparatus of claim 1, further comprising:
an additional capturer configured to capture images of the plurality of nozzles and disposed at a position different from a position of the capturer,
wherein the controller is further configured to control the supplier and the additional capturer to perform:
a sixth process of causing the additional capturer to capture images of the plurality of nozzles located at the processing position when the processing liquids are not being injected from the plurality of nozzles;
a seventh process of detecting the tip end portions of the plurality of nozzles based on the images captured in the sixth process;
an eighth process of detecting whether the droplet is hanging from the injection port of each of the tip end portions detected in the seventh process based on the images captured in the sixth process;
a ninth process of calculating the height of the droplet when the hanging droplet is detected in the eighth process; and
a tenth process of determining whether the abnormality exists based on the height of the droplet calculated in the ninth process.

12. The substrate processing apparatus of claim 1, wherein the controller is further configured to perform a sixth process of, when a brightness value of each of the images captured in the first process exceeds a predetermined threshold value, determining that each of the captured images is a high-brightness image, and
wherein the third process includes detecting whether the droplet is hanging from the injection port of each of the tip end portions detected in the second process, based on an image other than the high-brightness image among the images captured in the first process.

13. The substrate processing apparatus of claim 12, wherein the sixth process includes determining, when an average value of brightness values of a plurality of pixels in each of the images captured in the first process exceeds the threshold value, that each of the captured images is a high-brightness image.

14. The substrate processing apparatus of claim 12, wherein the sixth process includes determining, when a brightness value of a predetermined set region which is set in each of the images captured in the first process exceeds the threshold value, that each of the captured images is a high-brightness image, and
wherein the set region is a region of each of the captured images below a position of the injection port.

15. A substrate processing method, comprising:
a first step of capturing images of a plurality of nozzles held by an arm by a capturer when the plurality of nozzles are positioned at a processing position above a substrate held by a rotary holder and a supply of processing liquids to the plurality of nozzles is stopped;
a second step of detecting tip end portions of the plurality of nozzles based on the images captured in the first step;
a third step of detecting whether a droplet is hanging from an injection port of each of the tip end portions detected in the second step based on the images captured in the first step;
a fourth step of calculating a height of the droplet when the hanging droplet is detected in the third step; and
a fifth step of determining whether an abnormality exists based on the height of the droplet calculated in the fourth step.

16. The substrate processing method of claim 15, wherein the fifth step includes determining that the abnormality exists when the height of the droplet is equal to or greater than a predetermined value.

17. The substrate processing method of claim 15, wherein the second step includes detecting the tip end portions by an edge extraction process.

18. The substrate processing method of claim 15, wherein the third step includes detecting whether the droplet is hanging from the injection port of each of the tip end portions based on a shape of an object in contact with the injection port of each of the tip end portions.

19. The substrate processing method of claim 15, wherein the first step to the fifth step are performed during a period in which the plurality of nozzles image-captured by the capturer do not overlap with each other while the arm is moved.

20. A non-transitory computer-readable recording medium storing a substrate processing program that causes, by a computer, a substrate processing apparatus to perform the substrate processing method of claim 15.
